(19) United States
(12) Patent Application Publication
(10) Pub. No.: US 2026/0212925 A1
(43) Pub. Date: Jul. 23, 2026

(54) ULTRA-LARGE SCALE IN-MEMORY COMPUTING CORE CIRCUIT FOR RESOLVING IR-DROP ISSUES

(71) Applicant: HUAZHONG UNIVERSITY OF SCIENCE AND TECHNOLOGY, Hubei (CN)

(72) Inventors: Xingsheng Wang, Hubei (CN); Nan Li, Hubei (CN); Haozhe Lou, Hubei (CN); Fan Yang, Hubei (CN); Zifei Cai, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/452,816

(22) Filed: Jan. 19, 2026

(30) Foreign Application Priority Data
Jan. 21, 2025 (CN) 202510095240.2

(51) Int. Cl. G11C 13/00

(52) U.S. Cl. CPC G11C 13/0028; G11C 13/0026; G11C 13/004; G11C 2013/0042

(57) ABSTRACT

Disclosed is an ultra-large scale in-memory computing core circuit for solving IR-Drop issues. The disclosure determines that the accuracy degradation caused by line resistance is an approximate linear error by analyzing the inherent physical equations of the line resistance network. Through analysis of the approximate analytical equation, it is found that the linear error is only related to the parameters of the line resistance network. This means that different input voltage vectors produce the same approximate linear error of the column output current. Therefore, the disclosure adjusts the line resistance of rows and columns through co-design of devices, layout and circuit to maximize the linearization of the error, and eliminates these errors through adjacent differential pair readout design and sample resistance trimming; meanwhile, combined with the adjacent differential readout circuit, a fully differential ADC is designed to implement current isolation sampling and error compensation of line resistance.

### CROSS-REFERENCE TO RELATED APPLICATION

This application claims the priority benefit of China application serial no. 202510095240.2, filed on Jan. 21, 2025. The entirety of the above-mentioned patent application is hereby incorporated by reference herein and made a part of this specification.

### BACKGROUND

### Technical Field

The disclosure relates to microelectronics technology and artificial intelligence, and more specifically, relates to an ultra-large scale in-memory computing core circuit for solving IR-Drop problems.

### Description of Related Art

With the rapid advancement of artificial intelligence technology, particularly driven by deep learning algorithms, computing hardware encounters increasingly demanding performance requirements. Computing-In-Memory (CIM) technology, which integrates storage and computation in the same location, has garnered significant attention. CIM technology is recognized as one of the key technologies to address the computational power demands of AI, due to its notable advantages in providing substantial computational power, high energy efficiency, and low latency.

Memristors, as a type of non-volatile memory device, possesses the dual functionality of storage and computation. The unique physical characteristics of memristors endow memristors with substantial potential in compute-in-memory (CIM) applications. By integrating data storage and processing operations at a single location, memristors may significantly reduce data transmission distances, decrease power consumption, and enhance computational efficiency. Consequently, memristors are often regarded as a core component of CIM technology. The distinctive capabilities of memristors in data storage and processing offer the potential for achieving high-performance, energy-efficient, and low-latency AI hardware.

However, as the scale of memristor arrays expands, the presence of inter-wire resistance leads to an accumulation of voltage drop (IR-Drop) between nodes in the memristor array. This accumulation increasingly affects the voltage distribution within the array, thereby hindering the application of in-memory computing technology. Increasing the scale of the array may directly reduce the power consumption and area proportion of peripheral circuits, which results in improved computation throughput and efficiency. Nevertheless, IR-drop issues caused by line resistance between memory cells within the array limits the enhancement of scale and precision.

Currently, there are two primary technical methods for addressing line resistance. One method involves a hardware solution, which includes a redistribution of memristor conductance and circuit compensation. The redistribution approach employs an iterative algorithm to generate a redistribution of memristor conductance associated with line resistance, thereby ensuring that matrix computation results are consistent with those of the memristor array without line resistance. However, the redistribution of conductance requires additional computational load and a continuously distributed range of resistance states. The hardware compensation approach utilizes additional digital modules in peripheral digital circuits to correct output of ADC, which results in increased circuit consumption and processing time. The dual-power scheme mitigates line resistance issues by applying positive and negative voltages to two adjacent rows, but the single-core scale thereof remains limited to 144 k. This approach does not fundamentally resolve the line resistance issue in larger-scale arrays. The other method involves hardware-software co-design. This method integrates a line resistance network during a neural network training process. Such method largely depends on co-training of algorithms and hardware, which hinders the rapid deployment of algorithms and necessitates greater durability of memristors.

### SUMMARY

In light of the deficiencies or needs for improvement for the existing technology, the present disclosure provides an ultra-large scale in-memory computing core circuit for solving IR-Drop issues, thereby resolving the IR-drop problem caused by line resistance between memory cells in an array.

To achieve the above purpose, according to a first aspect of the disclosure, a line resistance network circuit of a non-volatile memory array is provided, including:
An ADC module, including M ADCs and voltage drivers connected to the M ADCs, forming M ADC channels;
A two-dimensional 1T1R array, having a word line control terminal WL parallel to a column current output terminal SL, wherein a bit line voltage signal input terminal BL is perpendicular to a word line and a source line, two adjacent columns of 1T1R constitute a differential pair of columns, which are provided for storing neural network weights;
A DAC module, including N DAC channels, each of the DAC channels includes a dual-ended differential readout circuit and an ADC connected in sequence;
The ADC module is connected to a bit line terminal of the two-dimensional 1T1R array, and a source line terminal of the two-dimensional 1T1R array is connected to the DAC module; a size of the two-dimensional 1T1R array is m×n, one of the DAC channels is shared by i rows in the array and controlled through time-division via a switch array, one of the ADC is shared by j columns in the array and controlled through time-division via the switch array, and j>i.

According to a second aspect of the disclosure, an electronic device is provided, including: a computer-readable storage medium and a processor;

The computer-readable storage medium is provided for storing executable instructions;

The processor is provided for reading the executable instructions stored in the computer-readable storage medium, and executing the method as described in the first aspect.

According to a third aspect of the disclosure, a computer-readable storage medium is provided, the computer-readable storage medium stores computer instructions, and the computer instructions are provided for enabling a processor to execute the method as described in the first aspect.

According to a fourth aspect of the disclosure, a computer program product is provided, including a computer program or instructions, and when the computer program or instructions are executed by a processor, the method as described in the first aspect is implemented.

In general, compared with the related art, the above technical scheme conceived by the disclosure may achieve the following advantageous effects:

The present disclosure addresses the accuracy degradation caused by line resistance by analyzing intrinsic physical equations of line resistance networks, determining that such degradation constitutes an approximately linear error. Upon analysis of an approximate analytical equation, it is identified that this linear error is solely dependent on the parameters of the line resistance network. This implies that different input voltage vectors yield an approximately identical linear error in the column output current. Therefore, the disclosure employs a co-design approach encompassing devices, layout, and circuitry to adjust the line resistance of rows and columns, thereby maximizing the linearization of the error. This is achieved through the adjacent differential pair readout design and the trimming of sampling resistances to eliminate these errors. Concurrently, in conjunction with the adjacent differential readout circuits, a fully differential ADC is designed and applied to enable isolated current sampling and line resistance error compensation. Through such circuit design, taking an example of a two-dimensional 1T1R array with dimensions M=128 and N=64, and a scale of 128 rows by 128 columns, simulation verification demonstrates that the disclosure achieves an ultra-large scale array of 5 Mb level, with computational energy efficiency exceeding 13 TOPS/W and computational throughput surpassing 0.41 TOPS.

### BRIEF DESCRIPTION OF THE DRAWINGS

FIG. 1A, FIG. 1B, FIG. 1C, and FIG. 1D respectively represent a first schematic diagram of in-memory computation, a second schematic diagram of in-memory computation, a first diagram of upper electrode voltage distribution, a second diagram of upper electrode voltage distribution for a non-volatile memory array provided by an embodiment of the present disclosure.

FIG. 2A, FIG. 2B, FIG. 2C, and FIG. 2D respectively illustrate: a schematic diagram of line resistance output current fitting of a memristor array with dimensions of 128 rows by 128 columns as provided in an embodiment of the present disclosure, a schematic diagram of an error in linear fitting, a schematic diagram of a line resistance network model omitting a column line resistance RSL, and a schematic diagram of a line resistance network model represented as a one-dimensional π-type line resistance network model.

FIG. 3A, FIG. 3B, FIG. 3C, and FIG. 3D respectively represent schematic diagrams of differential current output results when RBL equals RSL provided by an embodiment of the present disclosure, a schematic diagram of the differential current output results after linear compensation, a schematic diagram of the differential current output results when RBL is greater than RSL, and a schematic diagram of the differential current output results after linear compensation.

FIG. 4 is a schematic diagram of an in-memory analog matrix computing core circuit provided by an embodiment of the present disclosure.

FIG. 5A is a schematic diagram of an in-memory analog matrix computing core circuit provided by an embodiment of the present disclosure. FIG. 5B, FIG. 5C, FIG. 5D, and FIG. 5E respectively represent a schematic diagram of a 1T1R array in an in-memory analog matrix computing core circuit provided by the embodiment in FIG. 5A of the present disclosure, a first schematic diagram of a readout circuit, a second schematic diagram of a readout circuit, and a trimming resistor adjustment circuit.

FIG. 6A, FIG. 6B, FIG. 6C, and FIG. 6D respectively illustrate a first circuit-layout co-optimization layout design diagram, a second layout design diagram, a schematic diagram of a memristor cell device structure in a 1T1R configuration, and a schematic diagram of simulation results provided by an embodiment of the present disclosure.

### DESCRIPTION OF THE EMBODIMENTS

In order to elucidate the objectives, technical solutions, and advantages of the present disclosure, the following provides a further detailed description of the disclosure in conjunction with the accompanying drawings and exemplary embodiments. It should be understood that the specific embodiments described herein are solely for the purpose of explaining the present disclosure and are not intended to limit the disclosure. Furthermore, the technical features involved in the various embodiments of the present disclosure described below can be combined with each other, provided there is no conflict between them.

A memristor array with line resistance (m rows and n columns) is a large-scale line resistance network with 2 mn nodes, which may be divided into two dimensions of rows and columns. The Kirchhoff's current law (KCL) equation of node (i, j) on A memory cell is:

$${I}_{p} ( i , j ) = {I}_{m} ( i , j + 1 ) + {I}_{p} ( i , j + 1 ) \qquad ( 1 )$$

Wherein Iₚ(i, j) is a line resistance current in i-th row and j-th column, Iₘ(i, j+1) is a memory cell current in i-th row and (j+1)-th column, Iₚ(i, j+1) is a line resistance current in i-th row and (j+1)-th column. The KCL equations of all top nodes in the i-th row are combined. After simulating the line resistance network by using a Spectre simulator, a voltage distribution of a top electrode shows a similar decreasing trend with different input voltages, which means that an output current of the array exhibits a high linearity.

Multiple different voltage vectors Vᵢₙ are randomly input into the memristor array, and linear fitting is performed within the column output current. A linear fitting result of the output current is as follows:

$${Iideal}_{j} = K \times {lact}_{j} + b = K \cdot ( Vin \cdot {Gm}_{j}^{T} ) + b \qquad ( 2 )$$

Wherein Iactⱼ is a current in the j-th column under different input voltage vectors, and Iidealⱼ is a current in the j-th column without line resistance. Through an analysis of the linear fitting result of the equation (2), a relative error of all column output currents is less than 1%, which indicates that the current error of the column has a high linearity. In order to maximize the linearization of the error, the line resistance network omitting the column line resistance is analyzed. Therefore, the two-dimensional line resistance network is reduced to a one-dimensional row line resistance network. The row line resistance network is a one-dimensional π-type resistance network. For this one-dimensional π-type resistance network, a voltage solution of the electrode on the memory cell may be obtained by solving the following second-order differential equation and boundary conditions.

$${G}_{BL} \cdot ( {V}_{( j )} - {V}_{( j - 1 )} ) - {G}_{BL} \cdot ( {V}_{( j )} - {V}_{( j + 1 )} ) - {G}_{mean} \cdot ( {V}_{( j )} ) = 0 \qquad ( 3 )$$

Wherein Gₘₑₐₙ represents an average conductance of the memristor array. An analytical solution may be expressed as follows:

$${V}_{t ( i , j )} = {V}_{i n ( i )} \cdot {k}_{j} = {V}_{i n ( i )} \cdot [ \frac{( F ( n - 1 ) - {( 1 + h )}^{- 1} ) \cdot F ( n - 1 )}{F ( n ) - F ( n - 1 ) \cdot {( 1 + h )}^{- 1}} \cdot F ( j ) - F ( j - 1 ) ] \qquad ( 4 )$$

In equation (4), h and function F are polynomial functions related to G_{BL} and Gₘₑₐₙ. A voltage solution Vₜ(i,j) in the i-th row reveals that all top node voltages are results related to Vᵢₙ(i) and coefficient kⱼ, wherein kⱼ is independent of Vᵢₙ(i). Therefore, a voltage solution of the electrode on all memory cells is as follows:

$$Vt = {Vin}^{T} \cdot K \qquad ( 5 )$$

Wherein Vₜ is a voltage vector of all top nodes, Vᵢₙ is an input vector, K is a coefficient vector derived from kⱼ in equation (4). The above derivation result of the top node voltage shows that under different Vᵢₙ inputs, the column output current error exhibits a high linearity. Meanwhile, a conclusion may also be drawn that a column line resistance R_{SL} only affects a bias b of the linear error in equation (2). This analysis result provides a method for circuit compensation. By reducing the column line resistance R_{SL}, the error may achieve a higher linearity. In addition, by using adjacent columns as differential pairs to store weights, the current output result may be expressed as follows:

$$Iideal = Ioutp - Ioutn \approx K \times ( Ioutp - Ioutn ) \qquad ( 6 )$$

In equation (6), Ioutp and Ioutn represent the positive and negative column output currents of the differential pair respectively. Iideal is an ideal current without line resistance after linear compensation. Due to adjacent differential pair structures, the bias b of the linear error is eliminated, and the remaining linear error coefficient k may be corrected by a sampling resistor. The neural network weights are mapped into the memristor array with line resistance, where adjacent columns store weights in the form of differential pairs. When R_{BL}>R_{SL}, an accuracy after linear compensation reaches 92.4%, which proves the feasibility of the differential linear compensation scheme.

Based on this, an embodiment of the disclosure provides a line resistance network circuit of a non-volatile memory array, including:
An ADC module, including M ADCs and voltage drivers connected to the M ADCs, forming M ADC channels;
A two-dimensional 1T1R array, having a word line control terminal WL parallel to a column current output terminal SL, wherein a bit line voltage signal input terminal BL is perpendicular to a word line and a source line, two adjacent columns of 1T1R constitute a differential pair of columns, which are provided for storing neural network weights;
A DAC module, including N DAC channels, each of the DAC channels includes a dual-ended differential readout circuit and an ADC connected in sequence;
The ADC module is connected to a bit line terminal of the two-dimensional 1T1R array, and a source line terminal of the two-dimensional 1T1R array is connected to the DAC module; a size of the two-dimensional 1T1R array is m×n, one of the DAC channels is shared by i rows in the array and controlled through time-division via a switch array, one of the ADC is shared by j columns in the array and controlled through time-division via the switch array, and j>i.

Specifically, the circuit provided by the disclosure includes:

M input DAC and driver circuit channels, which are provided for converting a digital domain input vector into an analog voltage input vector.

The non-volatile memory array based on the memristor 1T1R structure features the word line control terminal WL parallel to the column current output terminal SL, with the bit line voltage signal input terminal BL oriented perpendicular to both the word line and the source line. The two adjacent columns of 1T1R constitute a differential pair of columns, which are provided for storing neural network weights. The layout of the array employs a layout-circuit co-design approach to address the issue of IR-drop caused by line resistance, thereby enabling ultra-large scale circuit design with computing capabilities exceeding 0.4 TOPS@int8 and computing efficiency surpassing 13 TOPS/W@int8. Specifically, the 1T1R array employs a structure where the word line is parallel to the column current output SL, and the bit line voltage signal input terminal BL is perpendicular to both the word line and the source line. Voltage signals are preloaded onto the bit line terminal, followed by the application of pulse signals on the word line to execute matrix operations in the analog domain, with adjacent columns of 1T1R serving as a differential pair of columns for storing neural network weights.

The dual-ended differential readout circuit for the N-channel, along with the ADC, compensates for the voltage drop errors caused by line resistance in the circuit through the adjustment of trimming resistances.

M DACs are connected to the bit line terminals of a storage array described in item b to a apply voltage to the array. The source line terminals of the array described in item b are connected to the ADC and the readout circuit described in item c for signal readout.

The storage array is composed of m rows and n columns, wherein a DAC and a drive circuit channel are shared by the i-th row of the array, controlled on a time-division basis through a switch array. Similarly, an ADC and a readout circuit channel are shared by the j-th column of the array, also controlled on a time-division basis through the switch array. To ensure effective compensation, it is necessary that j be greater than i, thereby ensuring that the row line resistance exceeds the column line resistance.

Preferably, the two-dimensional 1T1R array is configured in a rectangular layout, and a length of the rectangle is greater than a width of the rectangle.

Specifically, by employing Design Technology Co-Optimization (DTCO), the 1T1R memory cell is configured as a rectangle in the layout, with the length being greater than the width, resulting in the bit line resistance being greater than the source line resistance. This design maximizes the linearization of the error caused by line resistance, thereby facilitating subsequent error compensation by peripheral circuits.

Preferably, the dual-ended differential readout circuit adopts a folded cascode configuration as a differential input stage, with NMOS transistors serving as a common-source amplification output stage. This configuration is utilized for voltage clamping and current isolation sampling of the two adjacent columns of 1T1R. The sampled current is converted into a voltage through a trimming resistance adjustment circuit.

Specifically, the dual-ended differential readout circuit performs voltage clamping and isolated current sampling on the two adjacent columns of 1T1R. The sampled current is then converted into voltage through trimming resistance, which not only compensates for line resistance errors but also facilitates sampling for the ADC.

The dual-ended differential readout circuit employs a folded cascode configuration as the differential input stage, with an NMOS serving as the common-source amplification output stage. This setup is utilized for differential readout of the voltage at the SL terminal of the clamping array. Furthermore, the output stage incorporates NMOS mirror transistors for isolating and sampling the current, which is then output to the ADC for quantization. The isolated and sampled current passes through a trimming resistance adjustment circuit to compensate for line resistance errors. The offset term of the linear error is eliminated through differential pair subtraction, while the proportional term of the linear error is compensated through the trimming resistor adjustment circuit.

Preferably, the DAC is a C-2C DAC, and the voltage driver is a Class AB output operational amplifier.

The C-2C DAC is utilized to convert the original digital signal into an analog voltage signal, which is subsequently driven through a Class AB output operational amplifier serving as a voltage driver to drive the BL terminal of the array.

Preferably, the source line is implemented using a top metal layer, which has a lower sheet resistance compared to a bottom metal layer used for a bit line; the bit line is implemented using an M2 metal layer or an M3 metal layer; the source line is implemented using a top M6 metal layer.

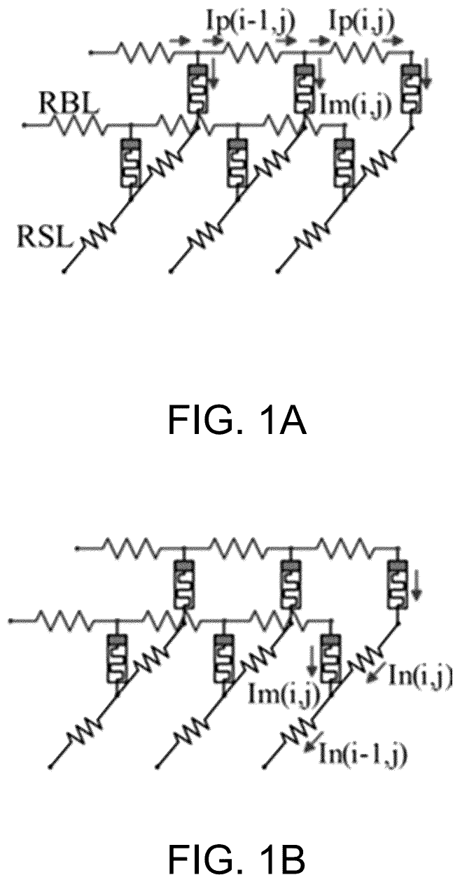

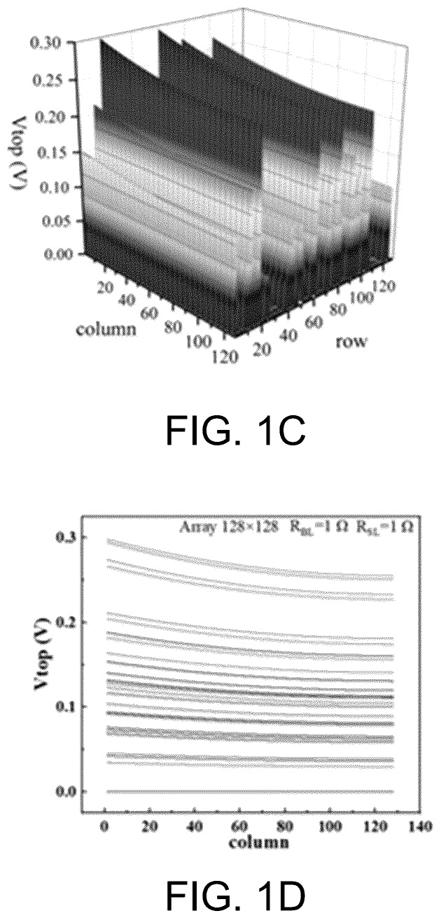

FIGS. 1A to 1D illustrate in-memory computation based on a non-volatile memory array, where the array includes 128 rows and 128 columns, with both the row line resistance RBL and column line resistance RSL being 1 ohm. As depicted in FIG. 1A and FIG. 1B, voltage excitation is applied to the bit line BL at a left end of a crossbar array (i.e., the bit line voltage signal input terminal), and a bottom terminal (i.e., the column current output terminal) of the array is clamped to a fixed level at the source line. Analog domain matrix multiplication is performed in accordance with Kirchhoff's theorem, resulting in the output current at the SL terminal. FIG. 1C and FIG. 1D illustrate a voltage distribution of upper electrodes. When mapped onto a two-dimensional plane, it can be observed that there is a similar voltage distribution trend across the upper electrodes. This distribution trend reveals the presence of output current.

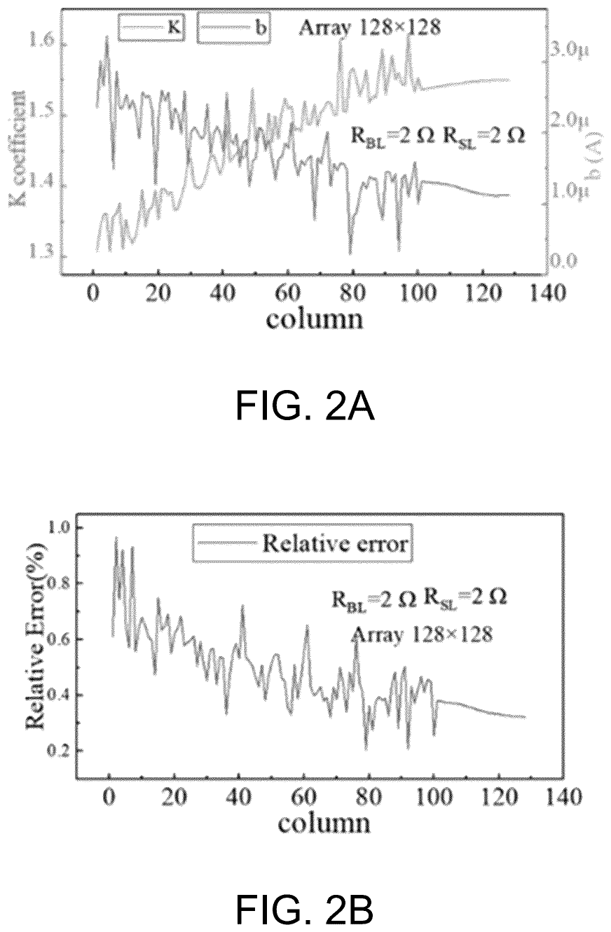

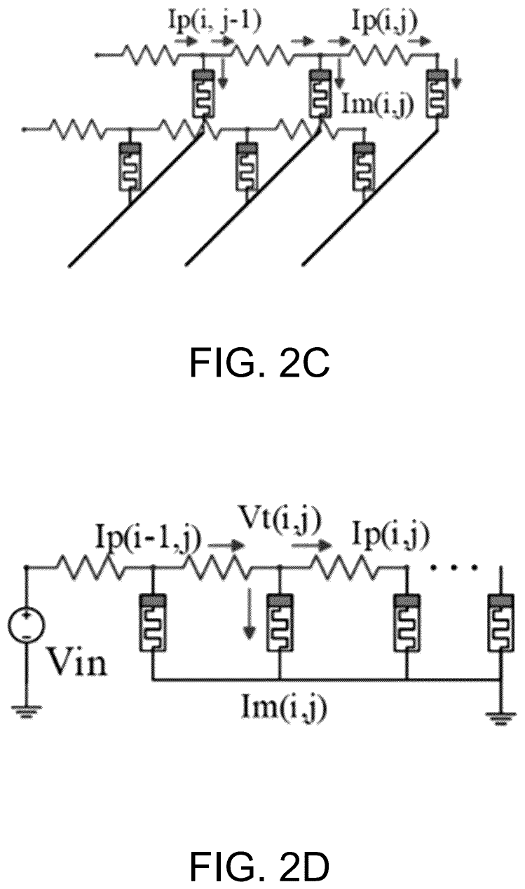

FIGS. 2A to 2D present results of linear fitting of the output current of line resistance. In FIG. 2A, a memristor array of 128 rows by 128 columns is shown, where the output current is fitted by equation (2) Iidealⱼ=K×Iactⱼ+b, wherein K is a linear coefficient of the linear fitting, and b is the linear offset. FIG. 2B demonstrates the error of the linear fitting, showing that the linear fitting error is less than 1%, thereby sufficiently proving the linearity of the output current. FIG. 2C illustrates the line resistance network model, omitting the column line resistance RSL. By isolating the network model in FIG. 2C, FIG. 2D shows that the line resistance network model is a one-dimensional π-type line resistance network model. By solving the differential equation of the one-dimensional π-type line resistance network, as expressed in equation (3), an analytical solution for the voltage distribution across the memory cell electrodes may be obtained. The analytical solution, given by equation (4), demonstrates that the current result may achieve a high degree of linearization, with the core issue being how to reduce the column line resistance.

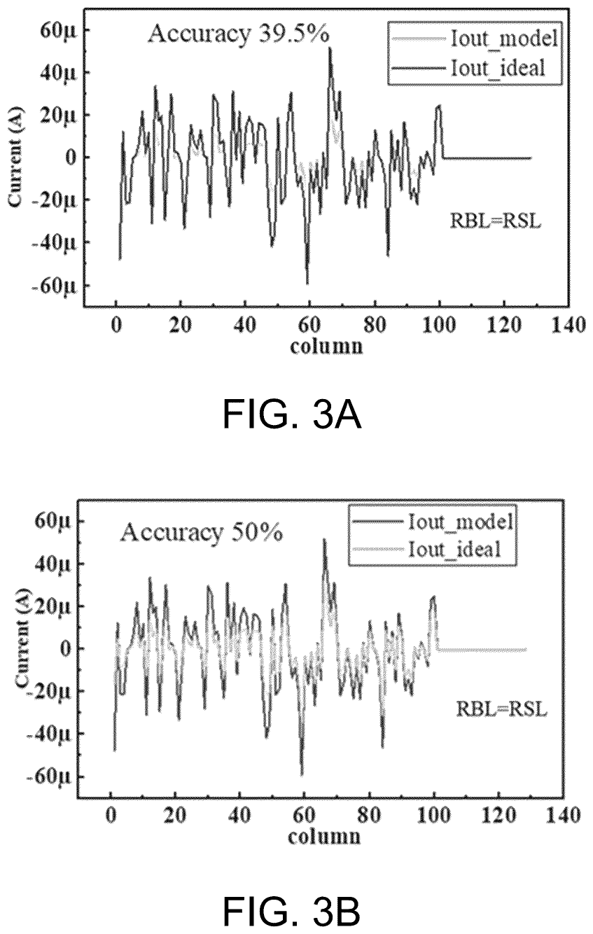

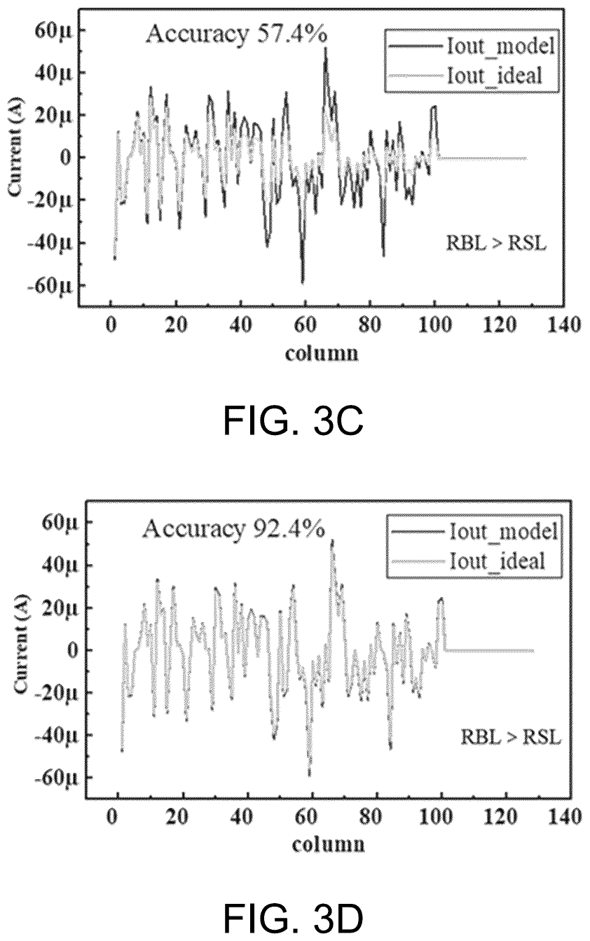

FIGS. 3A to 3D present a comparison of current results with linear compensation. The results obtained from FIGS. 2A to 2D indicate that increasing the row line resistance RBL and decreasing the column line resistance RSL may achieve maximum linearization of line resistance error. FIG. 3A shows the differential current output results with RBL=RSL, where the error due to line resistance reaches 60%. After implementing the linear compensation scheme, the error due to line resistance remains at 50%. FIG. 3C illustrates the layout optimization results where RBL>RSL, and in the absence of a line resistance compensation scheme, the error due to line resistance reaches 43%. FIG. 3D demonstrates the results after applying the linear compensation scheme, where the error due to line resistance is reduced to only 7.6%. This simulation result substantiates the feasibility of the linear error compensation scheme following layout optimization.

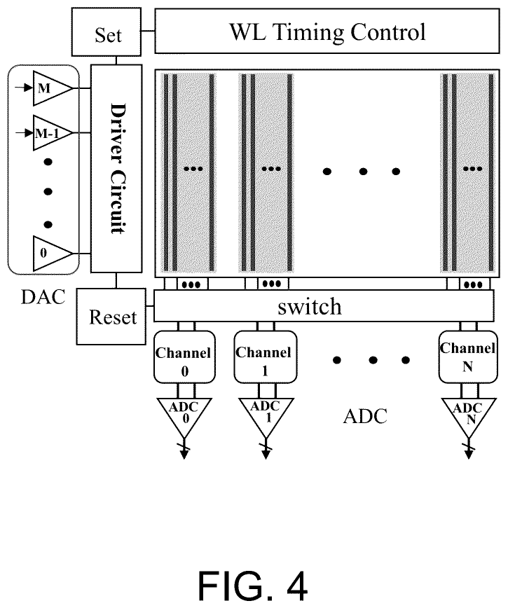

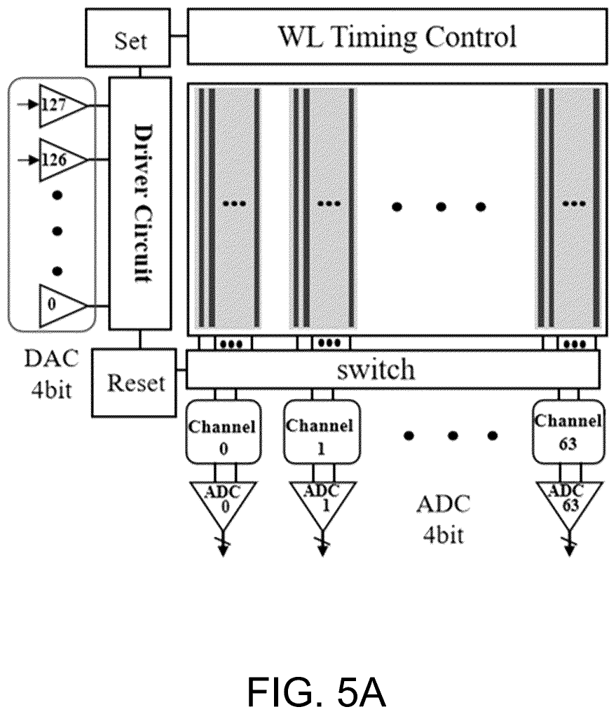

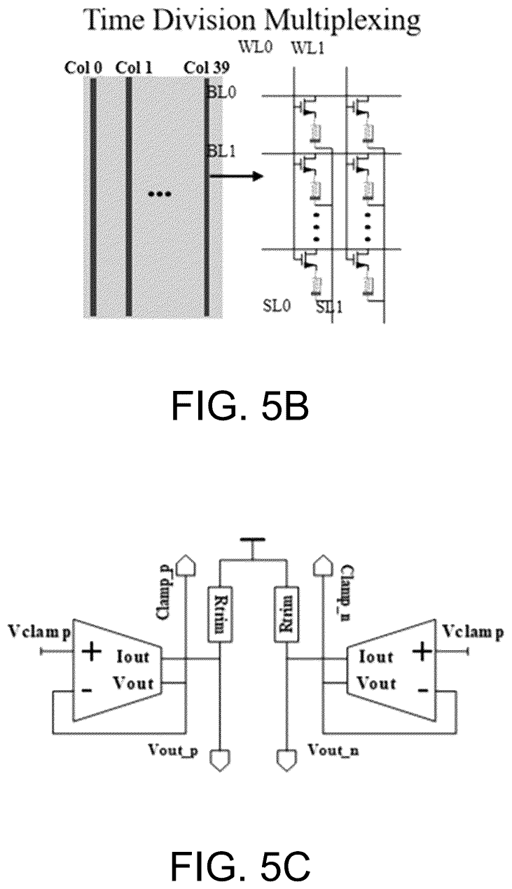

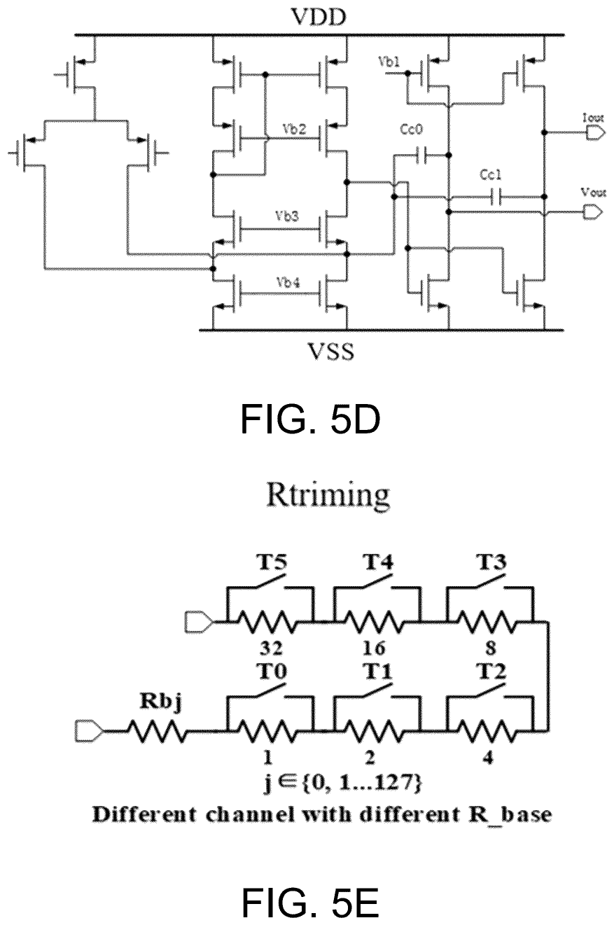

FIG. 4 illustrates a linear compensation scheme based on the aforementioned description, specifically the in-memory analog matrix computing core circuit provided by the present disclosure. Taking M=128 and N=64 as an example, within a two-dimensional 1T1R array of 128 rows by 128 columns, the present disclosure has designed and verified a 5 Mb array matrix computing core through layout-circuit co-optimization. This matrix computing core achieves superior computational throughput and efficiency while meeting the required computational accuracy. Based on SIMC 55 nm technology, the design of the CIM macro is depicted in FIG. 4. To satisfy the condition where RBL is greater than RSL, the design employs M DAC input channels and N ADC and readout circuit channels, as shown in FIG. 4. Since the area of DACs and ADCs is significantly larger than that of a 1T1R cell, one DAC input channel is shared by i rows. A sub-array selected by the switch control circuit participates in single-cycle computation, while the word lines (WLs) of other columns are turned off. As illustrated in FIGS. 5A and 5B, the two adjacent columns of 1T1R form differential pairs, collectively creating j/2 differential pairs. The readout circuit design for the output current is shown in FIG. 5C. Two clamping operational amplifiers are provided to read out the differential pair currents composed of two columns, which are then converted into voltage by two Rtriming circuits and sampled by ADCs. As depicted in FIG. 5D, a Vout port of the clamping operational amplifier is provided to clamp the column output of the array to Vclamp, where an output stage NMOS thereof mirrors a current Iout. Consequently, the column output current is isolated and sampled. As shown in FIG. 5E, linear compensation of the column output current is achieved by adjusting the sampling Rtriming.

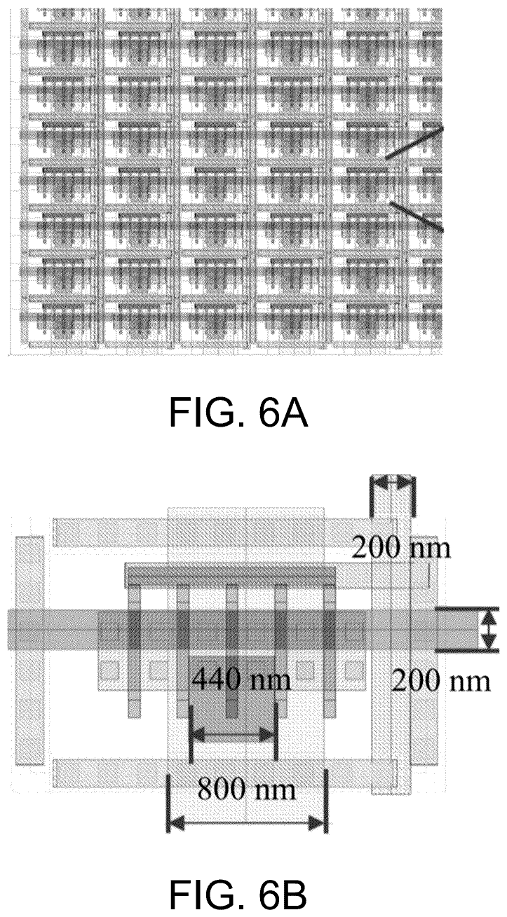

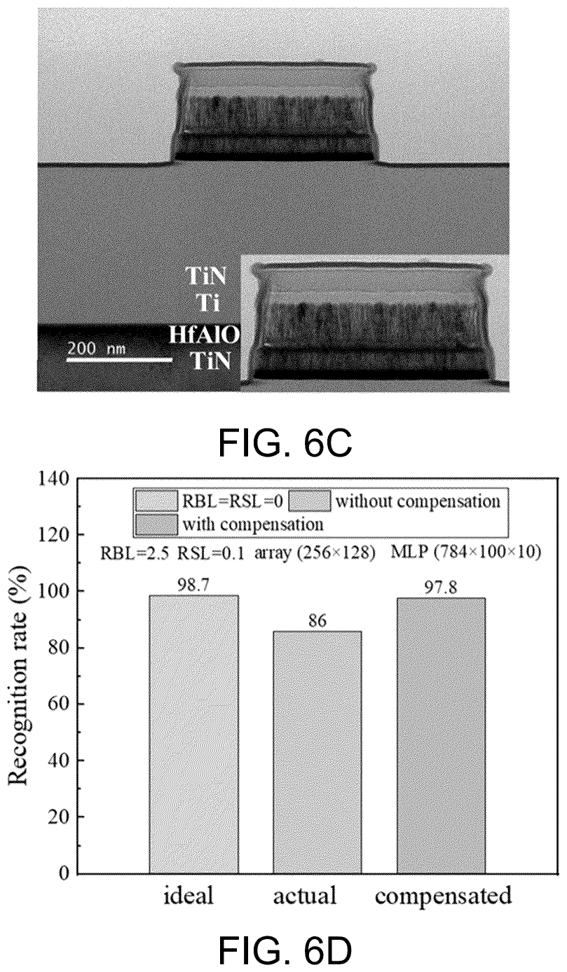

Through Design Technology Co-optimization (DTCO), the disclosure facilitates co-design across circuit, layout, and device levels. FIGS. 6A to 6D illustrate the results of circuit-layout co-optimization achieved by the present disclosure. Based on error analysis results, in order to maximize the linearity of the error, the disclosure employs the layout design shown in FIG. 6A and FIG. 6B. The 1T1R cell is designed in a rectangular shape, ensuring that the width of the source line (SL) is greater than that of the bit line (BL). Additionally, the source line utilizes the top metal layer, which has a lower sheet resistance compared to the bottom metal layer used for the bit line. As depicted in FIG. 6C, the bit line in the array employs M2 & M3 metal layers, whereas the source line in the array utilizes the top M6 metal layer, featuring a lower sheet resistance. The memristor unit in the 1T1R employs the device structure shown in FIG. 6C. Post-simulation of the circuit is conducted, and extracted parasitic parameters are incorporated into the neural network simulation model based on the memristor in-memory computing core. The results indicate that a recognition rate of the neural network has been restored.

The aforementioned description will be readily understood by those skilled in the art as merely a preferred embodiment of the present disclosure and is not intended to limit the disclosure. Any modifications, equivalent substitutions, and improvements made within the spirit and principles of the present disclosure are intended to be encompassed within the scope to be protected by the present disclosure.

What is claimed is:

1. A line resistance network circuit of a non-volatile memory array, comprising:
a DAC module, comprising M DACs and voltage drivers connected to the M DACs, forming M DAC channels;
a two-dimensional 1T1R array, having a word line control terminal WL parallel to a column current output terminal SL, wherein a bit line voltage signal input terminal BL is perpendicular to the word line control terminal WL and the column current output terminal SL, two adjacent columns of 1T1R constitute a differential pair of columns, which are provided for storing neural network weights; and
an ADC module, comprising N ADC channels, each of the ADC channels comprising a dual-ended differential readout circuit and an ADC connected in sequence;
wherein the DAC module is connected to the bit line voltage signal input terminal BL of the two-dimensional 1T1R array, and the column current output terminal SL of the two-dimensional 1T1R array is connected to the ADC module, a size of the two-dimensional 1T1R array is m×n, one of the ADC channels is shared by i rows in the array and controlled through time-division via a switch array, one of the DACs is shared by j columns in the array and controlled through time-division via the switch array, and j>i;
the two-dimensional 1T1R array is configured in a rectangular layout, and a length of the rectangle is greater than a width of the rectangle;
the dual-ended differential readout circuit adopts a folded cascode configuration as a differential input stage, with NMOS transistors serving as a common-source amplification output stage, which is utilized for voltage clamping and current isolation sampling of the two adjacent columns of 1T1R, the sampled current is converted into a voltage through a trimming resistance adjustment circuit.

2. The circuit according to claim 1, wherein the DAC is a C-2C DAC, and the voltage driver is a Class AB output operational amplifier.

3. The circuit according to claim 1, wherein the column current output terminal SL is implemented using a top metal layer, which has a lower sheet resistance compared to a bottom metal layer used for the bit line voltage signal input terminal BL.

4. The circuit according to claim 1, wherein the bit line voltage signal input terminal BL is implemented using an M2 metal layer or an M3 metal layer.

5. The circuit according to claim 1, wherein the column current output terminal SL is implemented using a top M6 metal layer.
